(19) United States
(12) Patent Application Publication
(10) Pub. No.: US 2014/0083468 A1
(43) Pub. Date: Mar. 27, 2014

(54) SUBSTRATE PROCESSING APPARATUS

(71) Applicant: EBARA CORPORATION, Tokyo (JP)

(72) Inventors: Mitsuru MIYAZAKI, Tokyo (JP); Kenichi KOBAYASHI, Tokyo (JP); Teruaki HOMBO, Tokyo (JP); Akira IMAMURA, Tokyo (JP); Boyu DONG, Tokyo (JP); Hiroyuki SHINOZAKI, Tokyo (JP)

(73) Assignee: EBARA CORPORATION, Tokyo (JP)

(21) Appl. No.: 14/038,603

(22) Filed: Sep. 26, 2013

(30) Foreign Application Priority Data
Sep. 27, 2012 (JP) 2012-213962
Sep. 19, 2013 (JP) 2013-193712

(51) Int. Cl. H01L 21/67

(52) U.S. Cl. CPC H01L 21/6719; H01L 21/67207
USPC 134/82; 15/88.3

(57) ABSTRACT

A substrate processing apparatus has a cleaning section for cleaning a substrate such as a semiconductor wafer and can be used as a polishing apparatus. The substrate processing apparatus includes a first cleaning chamber which houses at least one first cleaning module and two second cleaning modules arranged in a vertical array, a second cleaning chamber which houses two third cleaning modules arranged in a vertical array, and a first transport robot housed in a first transport chamber disposed between the first cleaning chamber and the second cleaning chamber. The first transport robot is configured to transfer substrates between the first cleaning module, the second cleaning modules, and the third cleaning modules.

### CROSS REFERENCE TO RELATED APPLICATION

This document claims priorities to Japanese Patent Application No. 2012-213962, filed Sep. 27, 2012 and Japanese Patent Application No. 2013-193712, filed Sep. 19, 2013, the entire contents of which are hereby incorporated by reference.

### BACKGROUND OF THE INVENTION

1. Field of the Invention

The present invention relates to a substrate processing apparatus, and more particularly to a substrate processing apparatus that has a cleaning section for cleaning a substrate such as a semiconductor wafer and can be used as a polishing apparatus, for example.

2. Description of the Related Art

Heretofore, in a cleaning process for cleaning an oxide film on a surface of a substrate, it is necessary to combine a cleaning step by acid chemicals and a cleaning step by alkaline chemicals, and perform a finishing cleaning step, and then perform a rinsing and drying step. Therefore, a number of cleaning modules must be prepared for performing the cleaning process.

If a roll scrub cleaning module is used as a cleaning module to perform roll scrub cleaning of an oxide film or the like on a surface of a substrate using acid chemicals, then not only particles to be removed tend to reattach to the surface of the substrate, but also the roll scrub cleaning module itself is likely to be damaged and the problem of acid removal from the substrate occurs. Therefore, in the case where the surface of the substrate is scrub-cleaned by the roll scrub cleaning module using the acid chemicals, after the roll scrub cleaning, the substrate is required to be rinsed with pure water or the like.

As a substrate processing apparatus for processing a substrate such as a semiconductor wafer, there has been widely known an apparatus which has a plurality of cleaning modules such as a brush cleaning unit and a jet water cleaning apparatus arranged in series for processing (cleaning) a substrate while the substrate is being transported in one direction.

In the case where a plurality of cleaning modules are arranged linearly, if the number of cleaning modules is increased for a higher throughput or a greater number of cleaning steps, then the footprint (installation area) of the substrate processing apparatus becomes larger. Further, because the substrate is processed while it is being transported in one direction, the sequence of cleaning steps remains unchanged at all times, and thus the cleaning steps to respond to a change in properties or the like of a film on the surface of the substrate cannot be performed.

The applicant of the present application has proposed a substrate processing apparatus designed to achieve an increased throughput without increasing the footprint thereof, as disclosed in Japanese laid-open patent publication No. 2010-50436. The proposed substrate processing apparatus includes a first cleaning chamber which houses a plurality of first cleaning modules arranged in a vertical direction, a second cleaning chamber which houses a plurality of second cleaning modules arranged in a vertical direction, and a transport robot housed in a transport chamber disposed between the first cleaning chamber and the second cleaning chamber, for transferring substrates between the first cleaning modules in the first cleaning chamber and the second cleaning modules in the second cleaning chamber.

In the substrate processing apparatus disclosed in Japanese laid-open patent publication No. 2010-50436, a substrate to be processed is first transferred to the first cleaning module where cleaning (primary cleaning) of the substrate is performed, and then the substrate is transferred to the second cleaning module where cleaning (secondary cleaning) of the substrate is performed. Therefore, in the substrate processing apparatus disclosed in Japanese laid-open patent publication No. 2010-50436, it is impossible to initially transfer a substrate to the second cleaning module where cleaning (primary cleaning) of the substrate is performed and thereafter to transfer the substrate to the first cleaning module where cleaning (secondary cleaning) of the substrate is performed.

Further, if the first cleaning module comprises a roll scrub cleaning module to perform roll scrub cleaning of an oxide film or the like on the surface of the substrate using acid chemicals, it is necessary to rinse the substrate with pure water or the like after the roll scrub cleaning, as described above. Furthermore, in the case where a large amount of slurry and polishing debris are attached to a polished substrate, for example, the slurry and polishing debris are removed from the surface of the substrate by rinse cleaning, and then the substrate is cleaned by roll scrub cleaning, whereby the substrate is prevented from being damaged and particles are prevented from reattaching to the substrate while the substrate is being scrub-cleaned. However, the substrate processing apparatus disclosed in Japanese laid-open patent publication No. 2010-50436 fails to meet such demands.

### SUMMARY OF THE INVENTION

The present invention has been made in view of the above circumstances. It is therefore an object of the present invention to provide a substrate processing apparatus which is capable of flexibly dealing with a change of cleaning patterns so as to respond to different film properties of an oxide film or the like on a substrate, for example, while achieving an increased throughput and promoting space saving.

In order to achieve the above object, according to one aspect of the present invention, there is a substrate processing apparatus comprising: a first cleaning chamber which houses at least one first cleaning module and two second cleaning modules, the first cleaning module and the two second cleaning modules being arranged in a vertical array; a second cleaning chamber which houses two third cleaning modules arranged in a vertical array; and a first transport robot housed in a first transport chamber disposed between said first cleaning chamber and the second cleaning chamber, the first transport robot being configured to transfer substrates between the first cleaning module, the second cleaning modules, and the third cleaning modules.

According to the present invention, the substrate can be cleaned by the first cleaning module and then cleaned by either one of the two second cleaning modules in the first cleaning chamber, and thereafter the substrate can be further cleaned by the third cleaning module in the second cleaning chamber; or the substrate can be cleaned by either one of the two second cleaning modules in the first cleaning chamber and then cleaned by the first cleaning module in the first cleaning chamber, and thereafter the substrate can be further cleaned by the third cleaning module in the second cleaning chamber. Specifically, the initial cleaning is performed using the first cleaning module or performed using either one of the two second cleaning modules. Thus, one of the cleaning modules for the initial cleaning of the substrate can freely be selected. Consequently, the substrate processing apparatus can flexibly deal with a change of cleaning patterns so as to respond to different film properties of an oxide film or the like on the substrate, for example.

In a preferred aspect of the present invention, the substrate processing apparatus according to claim 1, wherein the first transport robot includes a lifting and lowering table which is vertically movable, and two hands mounted on the lifting and lowering table and configured to operate independently of each other for holding the substrates.

According to the present invention, transferring of substrates in complex patterns can be performed by a single first transport robot, and thus the overhead time can be reduced.

In a preferred aspect of the present invention, the first cleaning module comprises a rinsing cleaning module and each of the second cleaning modules comprises a roll scrub cleaning module.

According to the present invention, the substrate processing apparatus can flexibly select, depending on different film properties of an oxide film or the like on the substrate, a first cleaning pattern in which a substrate is scrub-cleaned by a roll scrub cleaning module using an acid chemical liquid, for example, and then rinsed by a rinsing cleaning module, or a second cleaning pattern in which a substrate having a large amount of slurry and polishing debris attached thereto is rinsed by a rinsing cleaning module to remove the slurry and the polishing debris, and then scrub-cleaned by a roll scrub cleaning module.

In a preferred aspect of the present invention, the first cleaning chamber houses the one first cleaning module; and the second cleaning chamber houses another first cleaning module, the another first cleaning module and the third cleaning modules being arranged in a vertical array in the second cleaning chamber.

According to the present invention, the two first cleaning modules are used to form two cleaning lines, each extending through the first cleaning module, the second cleaning module, and the third cleaning module. In this case, even if the first cleaning module having a large height is used, the full height of the first cleaning chamber is prevented from being larger than the full height of the second cleaning chamber.

In a preferred aspect of the present invention, the substrate processing apparatus further comprises a drying chamber which houses two drying modules arranged in a vertical array; a second transport robot housed in a second transport chamber disposed between the drying chamber and the second cleaning chamber, the second transport robot being configured to transfer substrates between the third cleaning modules in the second cleaning chamber and the drying modules in the drying chamber.

According to the present invention, it is possible to unload the substrate from the cleaning section after it is cleaned and dried.

According to another aspect of the present invention, there is a substrate processing apparatus comprising: a cleaning chamber which houses a plurality of cleaning modules arranged in a vertical array; a pair of rails disposed in the cleaning chamber and configured to support one of the cleaning modules; and at least three sets of rollers provided on a lower surface of the cleaning module and configured to move on the rails; wherein the pair of rails have recesses defined in upper surfaces thereof at positions aligned with the respective rollers when the cleaning module is located at a predetermined position in the cleaning chamber; and the pair of rails and the at least three sets of roller are configured such that only one set of rollers is located at position aligned with ones of the recesses of the pair of rails and at least the other two sets of rollers are held in contact with the pair of rails when the cleaning module is not located at the predetermined position in the cleaning chamber.

According to the present invention, when the cleaning modules are disposed at the predetermined positions in the cleaning chamber, the cleaning modules are positionally stabilized. When setting the cleaning module into the predetermined position in the cleaning chamber or unloading the cleaning module out of the cleaning chamber, the cleaning module is moved with the rollers traveling on the rails in the cleaning chamber. During movement of the cleaning module, because at least two sets of rollers do not fall into the recesses, the cleaning module can be moved easily and smoothly.

According to the present invention, while achieving an increased throughput and promoting space saving, the substrate can be cleaned by the first cleaning module and then cleaned by either one of the two second cleaning modules in the first cleaning chamber, and thereafter the substrate can be further cleaned by the third cleaning module in the second cleaning chamber; or the substrate can be cleaned by either one of the two second cleaning modules in the first cleaning chamber and then cleaned by the first cleaning module in the first cleaning chamber, and thereafter the substrate can be further cleaned by the third cleaning module in the second cleaning chamber. Specifically, the initial cleaning is performed using the first cleaning module or performed using either one of the two second cleaning modules. Thus, one of the cleaning modules for the initial cleaning of the substrate can freely be selected. Consequently, the substrate processing apparatus can flexibly deal with a change of cleaning patterns so as to respond to different film properties of an oxide film or the like on the substrate, for example.

### BRIEF DESCRIPTION OF THE DRAWINGS

FIG. 1 is a plan view showing the overall arrangement of a polishing apparatus as a substrate processing apparatus according to an embodiment of the present invention;

FIG. 2 is a plan view of a cleaning section of the polishing apparatus;

FIG. 3 is a front elevational view of the cleaning section;

FIG. 4 is a view showing the relationship between an upper rail and a second cleaning module at an upper part of a first cleaning chamber when the second cleaning module is located at a predetermined position in the first cleaning chamber;

FIG. 5 is a view showing the relationship between the upper rail and the second cleaning module at the upper part of the first cleaning chamber when the second cleaning module is not located at the predetermined position in the first cleaning chamber;

FIG. 6 is a view showing another relationship between the upper rail and the second cleaning module at the upper part of the first cleaning chamber when the second cleaning module is not located at the predetermined position in the first cleaning chamber;

FIG. 7 is a view showing the manner in which the second cleaning module at the upper part of the first cleaning chamber is set at a predetermined position in the first cleaning chamber;

FIG. 8 is a plan view of a first cleaning module;

FIG. 9 is a vertically sectional front elevational view of the first cleaning module;

FIG. 10 is a perspective view of a roll scrub cleaning machine in the second cleaning module;

FIG. 11 is a vertical cross-sectional view of a Rotagoni drier in a drying module;

FIG. 12 is a plan view of the Rotagoni drier in the drying module;

FIG. 13 is a plan view of a base shown in FIG. 11;

FIG. 14A is a plan view showing a substrate-support member and part of the base shown in FIG. 13;

FIG. 14B is a cross-sectional view taken along line A-A of FIG. 13;

FIG. 14C is a cross-sectional view taken along line B-B of FIG. 14B;

FIG. 15 is a view schematically showing the layout of a second magnet and a third magnet as viewed axially along the substrate-support member;

FIG. 16A is a plan view of the substrate-support member and part of an arm when the substrate-support member is lifted by a lifting mechanism;

FIG. 16B is a cross-sectional view taken along line A-A of FIG. 13, showing the position of the parts when the substrate-support member is lifted by the lifting mechanism;

FIG. 16C is a cross-sectional view taken along line C-C of FIG. 16B;

FIG. 17 is a view showing cleaning lines for substrates in the cleaning section;

FIG. 18 is a view showing other cleaning lines for substrates in the cleaning section;

FIG. 19 is a front elevational view of another cleaning section;

FIG. 20 is a view showing cleaning lines for substrates in the cleaning section shown in FIG. 19;

FIG. 21 is a view showing other cleaning lines for substrates in the cleaning section shown in FIG. 19;

FIG. 22 is a front elevational view of still another cleaning section;

FIG. 23 is a view showing cleaning lines for substrates in the cleaning section shown in FIG. 22; and

FIG. 24 is a view showing other cleaning lines for substrates in the cleaning section shown in FIG. 22.

### DETAILED DESCRIPTION OF THE PREFERRED EMBODIMENTS

A substrate processing apparatus according to embodiments of the present invention will be described below with reference to the accompanying drawings. Identical or corresponding parts are denoted by identical reference numerals throughout drawings and will not be described in duplication. In the embodiments, the present invention is applied to a polishing apparatus having a cleaning section. However, the present invention is also applicable to other substrate processing apparatuses such as a plating apparatus having a cleaning section.

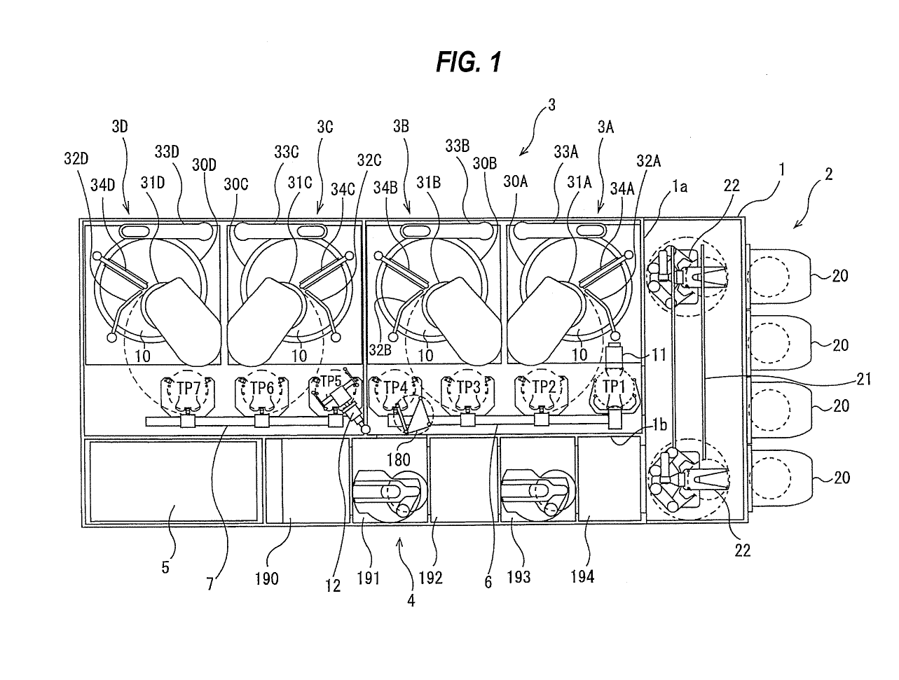

FIG. 1 is a plan view showing a whole arrangement of a substrate processing apparatus according to an embodiment of the present invention which is applied to a polishing apparatus. As shown in FIG. 1, the polishing apparatus (substrate processing apparatus) has a housing 1 in a rectangular form. An interior space of the housing 1 is divided into a loading/unloading section 2, a polishing section 3, and a cleaning section 4 by partition walls 1a and 1b. The loading/unloading section 2, the polishing section 3, and the cleaning section 4 are assembled independently of each other, and air is discharged from these sections independently of each other. The polishing apparatus further includes a controller 5 for controlling substrate processing operations.

The loading/unloading section 2 has two or more (four in this embodiment) front loading units 20 on which substrate cassettes, each storing plural substrates such as semiconductor wafers, are placed. The front loading units 20 are arranged adjacent to the housing 1 along a width direction of the polishing apparatus (a direction perpendicular to a longitudinal direction of the polishing apparatus). Each of the front loading units 20 is capable of receiving thereon an open cassette, an SMIF (Standard Manufacturing Interface) pod, or a FOUP (Front Opening Unified Pod). The SMIF and FOUP are a hermetically sealed container which houses a substrate cassette therein and is covered with a partition to thereby provide interior environments isolated from an external space.

The loading/unloading section 2 has a moving mechanism 21 extending along an arrangement direction of the front loading units 20. Two transport robots (loaders) 22 are installed on the moving mechanism 21 and are movable along the arrangement direction of the front loading units 20. The transport robots 22 are configured to move on the moving mechanism 21 so as to access the substrate cassettes mounted on the front loading units 20. Each transport robot 22 has vertically arranged two hands, which are separately used. The upper hand can be used for returning a processed substrate to the substrate cassette, and the lower hand can be used for taking out a substrate to be processed from the substrate cassette. The lower hand of the transport robot 22 is configured to rotate about its own axis, so that it can reverse the substrate.

The loading/unloading section 2 is required to be a cleanest area. Therefore, pressure in the interior of the loading/unloading section 2 is kept higher at all times than pressures in the exterior space of the polishing apparatus, the polishing section 3, and the cleaning section 4. On the other hand, the polishing section 3 is the dirtiest area, because slurry is used as a polishing liquid. Therefore, negative pressure is developed in the polishing section 3, and the pressure in polishing section 3 is kept lower than the internal pressure of the cleaning section 4. A filter fan unit (not shown) having a clean air filter, such as HEPA filter, ULPA filter or a chemical filter, is provided in the loading/unloading section 2. This filter fan unit removes particles, toxic vapor, and toxic gas from air to form flow of clean air at all times.

The polishing section 3 is an area where a surface of a substrate is polished (planarized). This polishing section 3 includes a first polishing unit 3A, a second polishing unit 3B, a third polishing unit 3C, and a fourth polishing unit 3D. The first polishing unit 3A, the second polishing unit 3B, the third polishing unit 3C, and the fourth polishing unit 3D are arranged along the longitudinal direction of the polishing apparatus.

The first polishing unit 3A includes a polishing table 30A to which a polishing pad 10 having a polishing surface is attached, a top ring 31A for holding a substrate and pressing the substrate against the polishing pad 10 on the polishing table 30A to polish the substrate, a polishing liquid supply nozzle 32A for supplying a polishing liquid and a dressing liquid (e.g., pure water) onto the polishing pad 10, a dresser 33A for dressing the polishing surface of the polishing pad 10, and an atomizer 34A for ejecting a mixture of a liquid (e.g., pure water) and a gas (e.g., nitrogen gas) or a liquid (e.g., pure water) in an atomized state onto the polishing surface of the polishing pad 10.

Similarly, the second polishing unit 3B includes a polishing table 30B to which a polishing pad 10 is attached, a top ring 31B, a polishing liquid supply nozzle 32B, a dresser 33B, and an atomizer 34B. The third polishing unit 3C includes a polishing table 30C to which a polishing pad 10 is attached, a top ring 31C, a polishing liquid supply nozzle 32C, a dresser 33C, and an atomizer 34C. The fourth polishing unit 3D includes a polishing table 30D to which a polishing pad 10 is attached, a top ring 31D, a polishing liquid supply nozzle 32D, a dresser 33D, and an atomizer 34D.

A substrate W may be polished by either one of the first polishing unit 3A, the second polishing unit 3B, the third polishing unit 3C, and the fourth polishing unit 3D. Alternatively, the substrate W may be polished successively by a plurality of polishing units selected from the first through fourth polishing units 3A through 3D. For example, the substrate W may be polished successively in the order of the first polishing unit 3A and the second polishing unit 3B, or may be polished successively in the order of the third polishing unit 3C and the fourth polishing unit 3D. Further, the substrate W may be polished successively in the order of the first polishing unit 3A, the second polishing unit 3B, the third polishing unit 3C, and the fourth polishing unit 3D. In any of these polishing sequences, the polishing times consumed respectively by the first through fourth polishing units 3A through 3D may be equalized to achieve an increased throughput of polished substrates.

A first linear transporter 6 is disposed adjacent to the first polishing unit 3A and the second polishing unit 3B. The first linear transporter 6 is a mechanism for transporting a substrate between four transport positions, i.e., a first transport position TP1, a second transport position TP2, a third transport position TP3, and a fourth transport position TP4 spaced successively from the loading/unloading section 2, arrayed along the direction in which the first polishing unit 3A and the second polishing unit 3B are arrayed.

A second linear transporter 7 is disposed adjacent to the third polishing unit 3C and the fourth polishing unit 3D. The second linear transporter 7 is a mechanism for transporting a substrate between three transport positions, i.e., a fifth transport position TP5, a sixth transport position TP6, and a seventh transport position TP7 spaced successively from the loading/unloading section 2, arrayed along the direction in which the third polishing unit 3C and the fourth polishing unit 3D are arrayed.

A substrate is transported to the first polishing unit 3A and the second polishing unit 3B by the first linear transporter 6. The top ring 31A of the first polishing unit 3A is movable between a polishing position and the second transport position TP2. Therefore, the transfer of the substrate to the top ring 31A is performed at the second transport position TP2. Similarly, the top ring 31B of the second polishing unit 3B is movable between a polishing position and the third transport position TP3. The transfer of the substrate to the top ring 31B is performed at the third transport position TP3. The top ring 31C of the third polishing unit 3C is movable between a polishing position and the sixth transport position TP6. The transfer of the substrate to the top ring 31C is performed at the sixth transport position TP6. The top ring 31D of the fourth polishing unit 3D is movable between a polishing position and the seventh transport position TP7. The transfer of the substrate to the top ring 31D is performed at the seventh transport position TP7.

A lifter 11 for receiving the substrate from the transport robot 22 is disposed in the first transport position TP1. The substrate is transferred from the transport robot 22 to the first linear transporter 6 by the lifter 11. The partition 1a has a shutter (not shown) positioned therein between the lifter 11 and the transport robot 22. When the substrate is to be transferred, the shutter is opened to allow the transport robot 22 to transfer the substrate to the lifter 11. A swing transporter 12 is disposed between the first linear transporter 6, the second linear transporter 7, and the cleaning section 4. The swing transporter 12 has a hand movable between the fourth transport position TP4 and the fifth transport position TP5. The transfer of the substrate from the first linear transporter 6 to the second linear transporter 7 is performed by the swing transporter 12. The substrate is transported by the second linear transporter 7 to the third polishing unit 3C and/or the fourth polishing unit 3D. Further, the substrate that has been polished in the polishing section 3 is transported to the cleaning section 4 by the swing transporter 12.

A temporary placement table 180 for temporarily placing a substrate thereon is installed on a frame (not shown) and disposed laterally of the swing transporter 12. The temporary placement table 180 is disposed adjacent to the first linear transporter 6 and positioned between the first linear transporter 6 and the cleaning section 4. The substrate that has been temporarily placed on the temporary placement table 180 is transported to the cleaning section 4 by a transport robot of the cleaning section 4 to be described below.

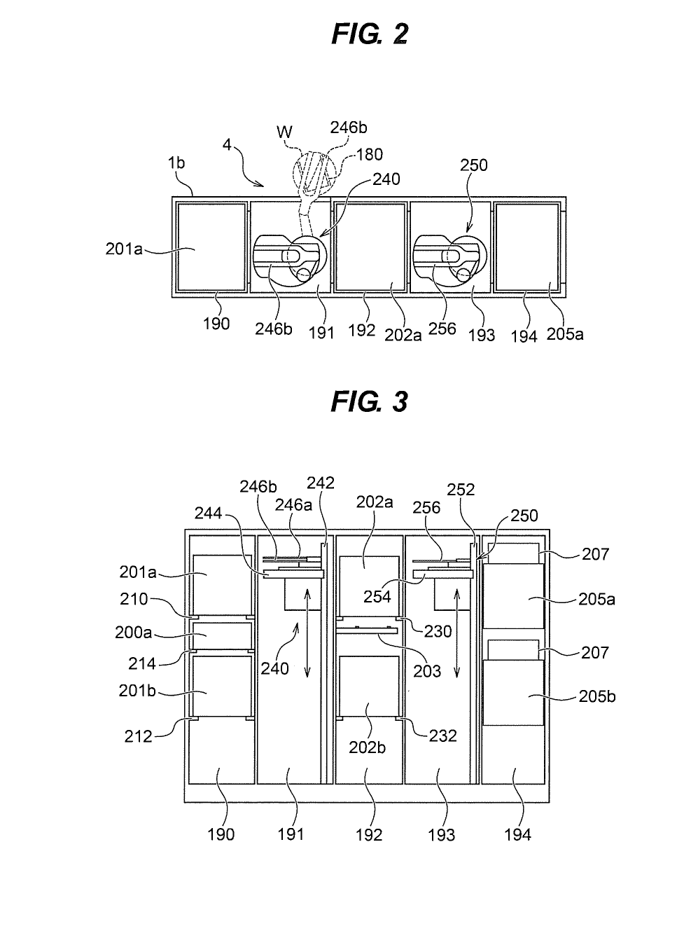

FIG. 2 is a plan view showing the cleaning section 4, and FIG. 3 is a front view showing the cleaning section 4. As shown in FIGS. 2 and 3, the cleaning section 4 is divided into a first cleaning chamber 190, a first transport chamber 191, a second cleaning chamber 192, a second transport chamber 193, and a drying chamber 194. The first cleaning chamber 190 houses therein a first cleaning module 200a and a pair of second cleaning modules 201a, 201b which are arranged in a vertical array with the first cleaning module 200a being vertically sandwiched between the second cleaning modules 201a, 201b. The second cleaning chamber 192 houses therein a pair of third cleaning modules 202a, 202b which are arranged in a vertical array.

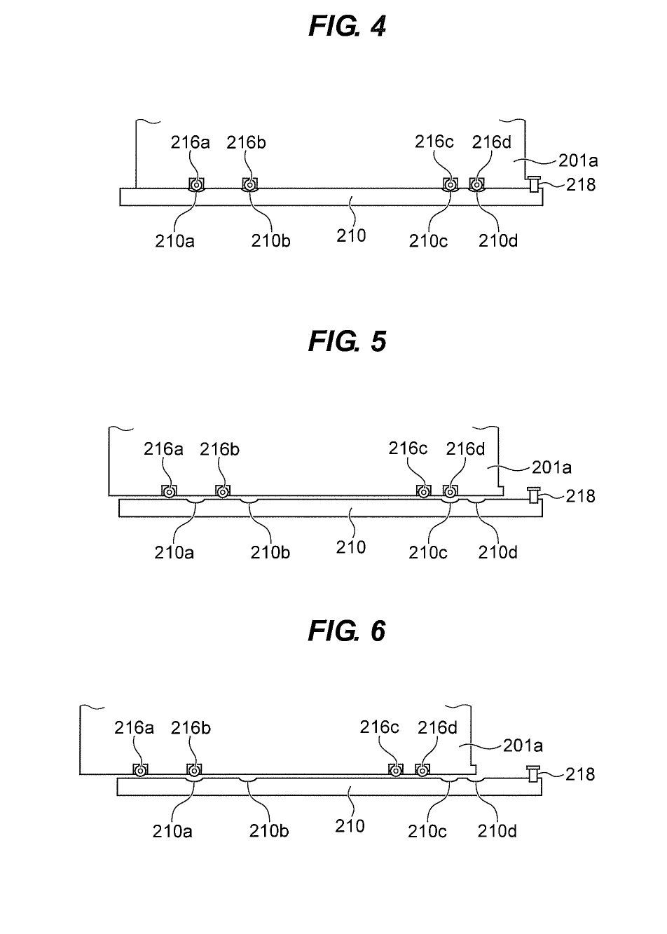

Each of the first cleaning module 200a, the second cleaning modules 201a, 201b, and the third cleaning modules 202a, 202b comprises a box-like cleaning module which houses therein a cleaning machine for cleaning a substrate using a cleaning liquid. Since the first cleaning module 200a, the second cleaning modules 201a, 201b, and the third cleaning modules 202a, 202b, which are in the form of a box, are arranged in vertical arrays, the cleaning section 4 has a reduced footprint (installation area). Further, as described below (see FIGS. 4 through 7), because the cleaning modules can be moved smoothly when the cleaning modules are set inside the cleaning chamber or removed from the cleaning chamber, the cleaning modules can be easily taken out of the cleaning section 4 and maintenance can be performed. Even during operation of the apparatus, without stopping the apparatus, only the cleaning modules for which maintenance is necessary can be taken out and the maintenance can be performed.

In the second cleaning chamber 192, a substrate station 203 for temporarily placing a substrate thereon is provided between the third cleaning modules 202a and 202b. The drying chamber 194 houses therein a pair of box-like drying modules 205a, 205b, having respective driers, spaced at a predetermined distance from each other and arranged in a vertical array. Filter fan units 207 for supplying clean air into the drying modules 205a, 205b are provided respectively at the upper parts of the drying modules 205a, 205b.

The second cleaning module 201a, which is disposed at an upper part of the first cleaning chamber 190, has a lower surface supported by a pair of upper rails 210 extending horizontally along side walls of the first cleaning chamber 190. The second cleaning module 201b, which is disposed at a lower part of the first cleaning chamber 190, has a lower surface supported by a pair of lower rails 212 extending horizontally along the side walls of the first cleaning chamber 190. The first cleaning module 200a, which is disposed at an intermediate part of the first cleaning chamber 190, has a lower surface supported by a pair of intermediate rails 214 extending horizontally along the side walls of the first cleaning chamber 190. The upper rails 210, the lower rails 212 and the intermediate rails 214 constitute part of a frame.

FIG. 4 is a side view showing the relationship between the second cleaning module 201a and the upper rail 210 in the first cleaning chamber 190. As shown in FIG. 4, at least three sets, four sets in this example, of rollers 216a, 216b, 216c, 216d capable of traveling on the upper rails 210 are provided on the lower surface of the second cleaning module 201a disposed at the upper part of the first cleaning chamber 190. The upper rails 210 have recesses 210a, 210b, 210c, 210d defined in upper surfaces thereof at positions aligned with the respective rollers 216a, 216b, 216c, 216d when the second cleaning module 201a is located at a predetermined position in the first cleaning chamber 190. When the second cleaning module 201a is brought into contact with stoppers 218 and is located at the predetermined position in the first cleaning chamber 190, all the rollers 216a through 216d enter the respective recesses 210a through 210d, and thus the lower surface of the second cleaning module 201a is seated on the upper surfaces of the upper rails 210. Accordingly, the second cleaning module 201a is positionally stabilized in the first cleaning chamber 190.

When the second cleaning module 201a is located at the predetermined position in the first cleaning chamber 190, all the four sets of rollers 216a through 216d enter the respective recesses 210a through 210d provided in the upper rails 210. However, when the second cleaning module 201a is not located at the predetermined position in the first cleaning chamber 190, at least three of the four sets of rollers 216a through 216d are kept in contact with the upper surfaces of the upper rails 210. For example, as shown in FIG. 5, when one set of rollers 216d is positioned in alignment with the recesses 210c, the other three sets of rollers 216a, 216b, 216c are kept in contact with the upper surfaces of the upper rails 210. Further, as shown in FIG. 6, when one set of rollers 216b is positioned in alignment with the recesses 210a, the other three sets of rollers 216a, 216c, 216d are kept in contact with the upper surfaces of the upper rails 210.

Consequently, when the second cleaning module 201a is located at the predetermined position in the first cleaning chamber 190, the second cleaning module 201a is positionally stabilized. When the second cleaning module 201a is set into the predetermined position in the first cleaning chamber 190 or taken out of the first cleaning chamber 190, the second cleaning module 201a can be moved with the rollers 216a through 216d along the upper rails 210 in the first cleaning chamber 190. When the second cleaning module 201a is moved, at least three of the four sets of rollers 216a through 216d do not fall into the recesses 210a through 210d, and thus the second cleaning module 201a can be moved easily and smoothly.

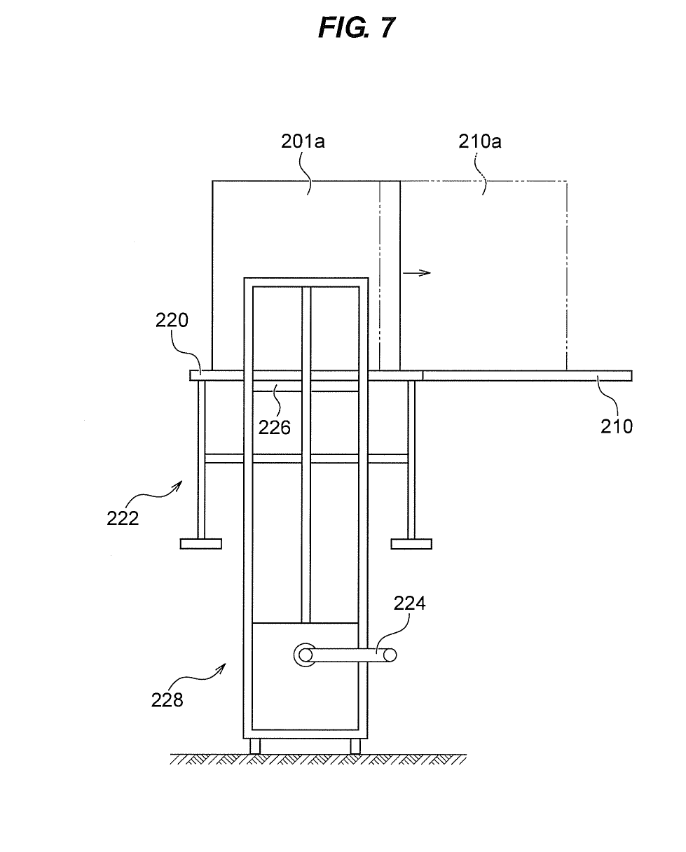

FIG. 7 is a view showing the manner in which the second cleaning module is set at the predetermined position in the first cleaning chamber. As shown in FIG. 7, when the second cleaning module 201a is set at the predetermined position in the first cleaning chamber 190, the second cleaning module 201a is placed on a carriage 222 having carriage rails 220 which have recesses at predetermined positions, in the same manner as the recesses 210a through 210d of the upper rails 210, in such a state that all the rollers 216a through 216d enters the corresponding recesses of the carriage rails 220. A lifter 228 having a fork 226 vertically movable by rotation of a handle 224 is disposed, and the carriage 222 on which the second cleaning module 201a is placed is supported by the fork 226 of the lifter 228. The fork 226 is lifted to lift the carriage 222 so that the carriage rails 220 reach the same height as the upper rails 210 in the first cleaning chamber 190. Then, the lifter 228 is moved laterally to join the carriage rails 220 to the upper rails 210.

In this state, the second cleaning module 201a on the carriage 222 is pushed into the first cleaning chamber 190 and is moved through the rollers 216a, 216b, 216c, 216d from the carriage rails 220 onto the upper rails 210 in the first cleaning chamber 190. Then, all the rollers 216a through 216d enter the respective recesses 210a through 210d of the upper rails 210, and the lower surface of the second cleaning module 201a is seated on the upper surfaces of the upper rails 210. When the second cleaning module 201a is brought into contact with the stoppers 218, the movement of the second module 201a is stopped.

Therefore, the second cleaning module 201a can reliably be set at the predetermined position in the first cleaning chamber 190. When the second cleaning module 201a is moved, at least three of the four sets of rollers 216a through 216d are kept in contact with the carriage rails 220 of the carriage 222 and the upper rails 210 in the first cleaning chamber 190 at all times, and thus the second cleaning module 201a can be moved smoothly.

Similarly, the second cleaning module 201b disposed at the lower part of the first cleaning chamber 190 and the first cleaning module 200a disposed at the intermediate part of the first cleaning chamber 190 also have at least three sets of rollers on their lower surfaces, and the lower rails 212 for supporting the second cleaning module 201b and the intermediate rails 214 for supporting the first cleaning module 200a also have at least three sets of recesses defined therein at their predetermined positions.

Further, as shown in FIG. 3, the third cleaning module 202a, which is disposed at an upper part of the second cleaning chamber 192, has a lower surface supported by a pair of upper rails 230 extending horizontally along side walls of the second cleaning chamber 192. The third cleaning module 202b, which is disposed at a lower part of the second cleaning chamber 192, has a lower surface supported by a pair of lower rails 232 extending horizontally along the side walls of the second cleaning chamber 192. The upper rails 230 and the lower rails 232 constitute part of a frame.

These third cleaning modules 202a, 202b also have at least three sets of rollers on their lower surfaces, and the upper rails 230 for supporting the third cleaning module 202a and the lower rails 232 for supporting the third cleaning module 202b also have at least three sets of recesses defined therein at their predetermined positions.

As shown in FIG. 3, a first transport robot 240 is disposed in the first transport chamber 191. The first transport robot 240 has a lifting and lowering table 244 vertically movable along a support shaft 242 extending vertically, and two hands 246a, 246b mounted on the lifting and lowering table 244 and being actuatable independently of each for holding substrates. As indicated by the dotted lines in FIG. 2, the first transport robot 240 is disposed in a position where the lower hand 246b is accessible to the temporary placement table 180. When the lower hand 246b of the first transport robot 240 accesses the temporary placement table 180, a shutter (not shown) provided in the partition 1b is opened.

As described above, the first transport robot 240 has the vertically movable lifting and lowering table 244, and the two hands 246a, 246b actuatable independently of each for holding substrates. By using the first transport robot 240, the transfer of substrates in complex patterns can be performed by the single transport robot to reduce the overhead time.

A second transport robot 250 is disposed in the second transport chamber 193. The second transport robot 250 has a lifting and lowering table 254 vertically movable along a support shaft 252 extending vertically. The lifting and lowering table 254 has a single hand 256 for holding a substrate.

The first transport robot 240 operates to transfer the substrate between the temporary placement table 180 and the substrate station 203, between the substrate station 203 and the first cleaning module 200a, between the first cleaning module 200a and one of the second cleaning modules 201a, 201b, and between one of the second cleaning modules 201a, 201b and one of the third cleaning modules 202a, 202b. Further, the first transport robot 240 also operates to transfer the substrate between the substrate station 203 and one of the second cleaning modules 201a, 201b. The first transport robot 240 can also operate to transfer the substrate between the temporary placement table 180 and the first cleaning module 200a and between the temporary placement table 180 and one of the second cleaning modules 201a, 201b.

The second transport robot 250 operates to transfer the substrate between one of the third cleaning modules 202a, 202b and one of the drying modules 205a, 205b. Since the second transport robot 250 transports only the substrate which has been cleaned, it has only one hand 256.

The transport robot 22 shown in FIG. 1 removes the substrate from one of the drying modules 205a, 205b using its upper hand, and returns the removed substrate back into the substrate cassette. When the upper hand of the transport robot 22 accesses the drying modules 205a, 205b, the shutter (not shown) provided in the partition 1a is opened.

The cleaning section 4 includes the single first cleaning module 200a, the two second cleaning modules 201a, 201b, and the two third cleaning modules 202a, 202b, and thus can provide a plurality of cleaning lines for cleaning a plurality of substrates in parallel. The cleaning line is defined as a transfer path of a substrate when the substrate is cleaned by a plurality of cleaning modules in the cleaning section 4.

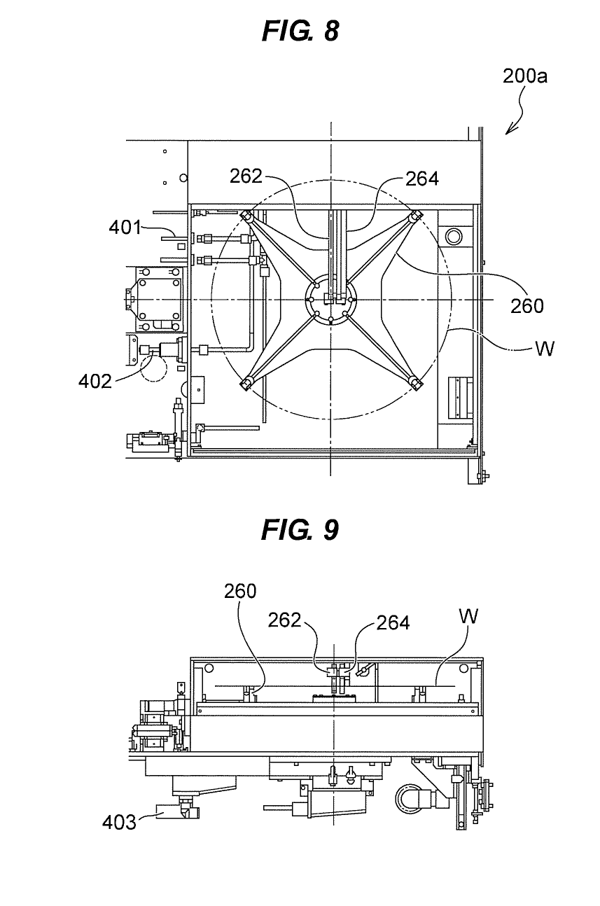

FIGS. 8 and 9 show the first cleaning module 200a. The first cleaning module 200a is in the form of a box surrounded by outer walls. The outer wall of the first cleaning module 200a has an opening for carrying in and out the substrate W, and a shutter which opens and closes the opening (not shown). The opening through which the substrate W is carried into and out of the cleaning module is provided at the side of the outer wall facing the transport chamber when the cleaning module is placed in the cleaning section. In this example, the first cleaning module 200a comprises a rinsing cleaning module having a rinsing cleaning machine therein. The first cleaning module 200a has a rotary chuck 260 for gripping and rotating a substrate W in a horizontal plane, a chemical liquid supply nozzle 262 disposed above the substrate W gripped by the rotary chuck 260, for supplying a chemical liquid such as HF to the surface (upper surface) of the substrate W, and a pure water supply nozzle 264 for supplying pure water as a rinsing liquid to the surface of the substrate W.

The first cleaning module 200a operates as follows: The rotary chuck 260 grips the substrate W and rotates the substrate W in a horizontal plane. While the substrate W is being rotated, the chemical liquid supply nozzle 262 supplies the chemical liquid such as HF to the surface (upper surface) of the substrate W to clean the surface of the substrate W. Thereafter, the pure water supply nozzle 264 supplies the pure water as a rinsing liquid to the surface of the substrate W to rinse the surface of the substrate W.

As shown in FIGS. 8 and 9, a pipe 401 for supplying pure water to the pure water supply water nozzle 264 is provided on the outer wall of the first cleaning module 200a, and a pipe 402 for supplying a chemical liquid to the chemical liquid supply nozzle 262 is provided on the outer wall of the first cleaning module 200a.

Further, a chemical liquid supply nozzle (not shown) for supplying a chemical liquid such as HF to the lower surface of the substrate W, and a pure water supply nozzle (not shown) for supplying pure water as a rinsing liquid to the lower surface of the substrate W are provided below the substrate W. Further, pipes for supplying pure water and a chemical liquid, respectively are provided on the outer wall or the bottom of the first cleaning module 200a, and these pipes are connected to the above respective nozzles. Furthermore, a discharge port for discharging waste liquid after cleaning, and a pipe 403 connected to the discharge port are provided at the bottom of the box-like first cleaning module 200a.

In this example, each of the second cleaning modules 201a, 201b and the third cleaning modules 202a, 202b comprises a roll scrub cleaning module having a roll scrub cleaning machine therein. The roll scrub cleaning modules of the second cleaning modules 201a, 201b and the third cleaning modules 202a, 202b are identical in structure to each other. The second cleaning module 201a will be described in detail below by way of example.

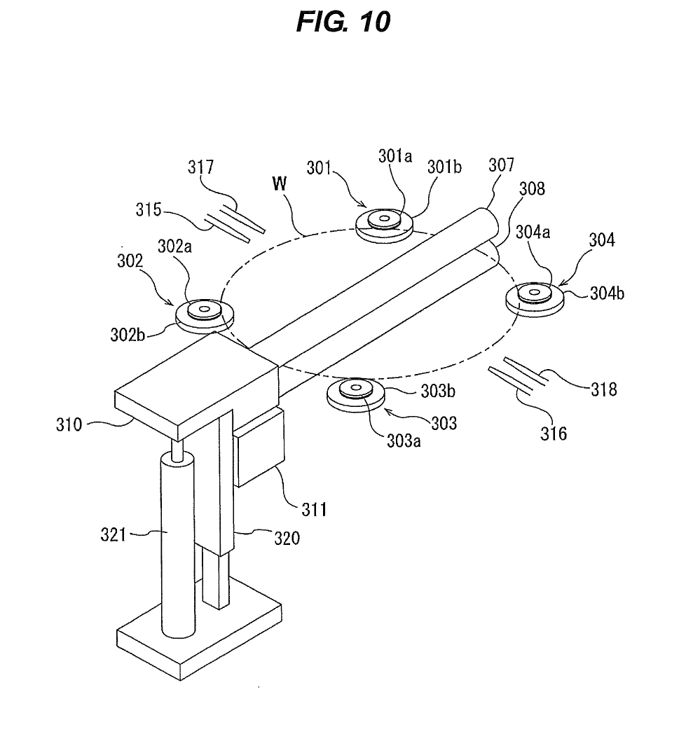

FIG. 10 is a perspective view showing the roll scrub cleaning machine inside the second cleaning module 201a. The second cleaning module 201a is in the form of a box surrounded by outer walls. The outer wall of the second cleaning module 201a has an opening for carrying in and out the substrate W, and a shutter which opens and closes the opening (not shown). As shown in FIG. 10, the roll scrub cleaning machine includes four rollers 301, 302, 303, 304 for holding and rotating a substrate W, a pair of roll sponges (cleaners) 307, 308 for contacting the upper and lower surfaces, respectively, of the substrate W, a pair of rotating mechanisms 310, 311 for rotating the roll sponges 307, 308, respectively, a pair of cleaning liquid supply nozzles 315, 316 for supplying a cleaning liquid, e.g., pure water, to the upper and lower surfaces of the substrate W, and a pair of etching liquid supply nozzles 317, 318 for supplying an etching liquid, e.g., a chemical liquid, to the upper and lower surfaces of the substrate W. The rollers 301, 302, 303, 304 are movable toward and away from each other by non-illustrated actuating mechanisms such as air cylinders.

The rotating mechanism 310 for rotating the upper roll sponge 307 is supported on a guide rail 320 for guiding the rotating mechanism 310 movable in a vertical direction. Further, the rotating mechanism 310 is supported by an elevating mechanism 321 for vertically moving the rotating mechanism 310 and the upper roll sponge 307. The rotating mechanism 311 for rotating the lower roll sponge 308 is supported on a guide rail (not shown), and the rotating mechanism 311 and the lower roll sponge 308 are vertically movable by an elevating mechanism (not shown). As the elevating mechanism, a motor-driven mechanism including a ball screw or an air cylinder is used.

When the substrate W is carried in and out, the roll sponges 307 and 308 are located away from each other. When cleaning the substrate W, the roll sponges 307 and 308 are moved closer to each other to contact the upper and lower surfaces of the substrate W. Forces of the roll sponges 307 and 308 pressing the upper and lower surfaces of the substrate W are controlled by the elevating mechanism 321 and the non-illustrated elevating mechanism. The upper roll sponge 307 and the rotating mechanism 310 are supported by the elevating mechanism 321 from below. Therefore, the pressing force of the upper roll sponge 307 against the upper surface of the substrate W can be adjusted from 0 [N].

The roller 301 has a two-stage structure comprising a holding portion 301a and a shoulder (supporting portion) 301b. The shoulder 301b has a diameter larger than a diameter of the holding portion 301a. The holding portion 301a is formed on the shoulder 301b. The rollers 302, 303, and 304 have the same structure as the roller 301. The substrate W carried by the lower arm of the first transport robot 209 is placed onto the shoulders 301b, 302b, 303b, and 304b. Then, the rollers 301, 302, 303, and 304 are moved toward the substrate W to bring the holding portions 301a, 302a, 303a, and 304a into contact with the substrate W, whereby the substrate W is held by the holding portions 301a, 302a, 303a, and 304a. At least one of the four rollers 301, 302, 303, and 304 is rotated by a rotating mechanism (not shown), whereby the substrate W is rotated with its periphery held by the rollers 301, 302, 303, and 304. The shoulders 301b, 302b, 303b, and 304b comprise tapered surfaces with downward gradient. With this configuration, the substrate W is kept out of contact with the shoulders 301b, 302b, 303b, and 304b while the substrate W is held by the holding portions 301a, 302a, 303a, and 304a.

Cleaning operation is performed as follows. First, the substrate W is held by the rollers 301, 302, 303, and 304, and rotated. Subsequently, the cleaning liquid is supplied from the cleaning liquid supply nozzles 315 and 316 onto the upper and lower surfaces of the substrate W. Then, the roll sponges 307 and 308 are rotated about their own axes and brought into sliding contact with the upper and lower surfaces of the substrate W, thereby scrub cleaning the upper and lower surfaces of the substrate W. After the roll scrub cleaning process, the roll sponge 307 is moved upward and the roll sponge 308 is moved downward. Then, the etching liquid is supplied from the etching liquid supply nozzles 317 and 318 onto the upper and lower surfaces of the substrate W to perform etching (chemical cleaning) of the upper and lower surfaces of the substrate W.

In this example, the third cleaning modules 202a and 202b uses a roll scrub cleaning module having the same structure as the second cleaning module 201a. For example, the third cleaning modules 202a and 202b may be a pencil scrub cleaning module or a two-fluid-jet cleaning module. The two-fluid-jet cleaning module comprises a cleaning module configured to produce a mixture of an N₂ gas and pure water (DIW) containing a small amount of CO₂ gas (carbon dioxide gas) dissolved therein, and to eject the mixture of the N₂ gas and the pure water onto the surface of the substrate. This type of cleaning module can remove fine particles on the substrate by fine droplets and impact energy. In particular, substrate cleaning with no damage can be realized by appropriately adjusting a flow rate of the N₂ gas and a flow rate of the pure water. Further, use of the pure water containing the carbon dioxide gas dissolved therein can prevent corrosion of the substrate that could be caused by static electricity.

Structural details of the drying modules 205a, 205b will be described below. The drying modules 205a, 205b are identical in structure to each other in that each of the drying modules 205a, 205b comprises a module having a Rotagoni drier for performing a Rotagoni drying process therein. The drying module 205a will be described in detail below by way of example.

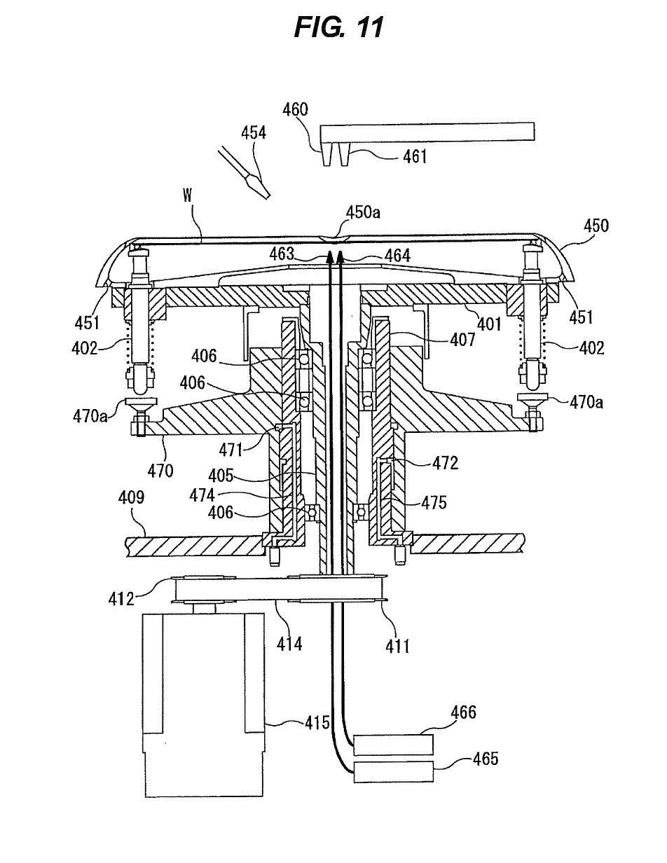

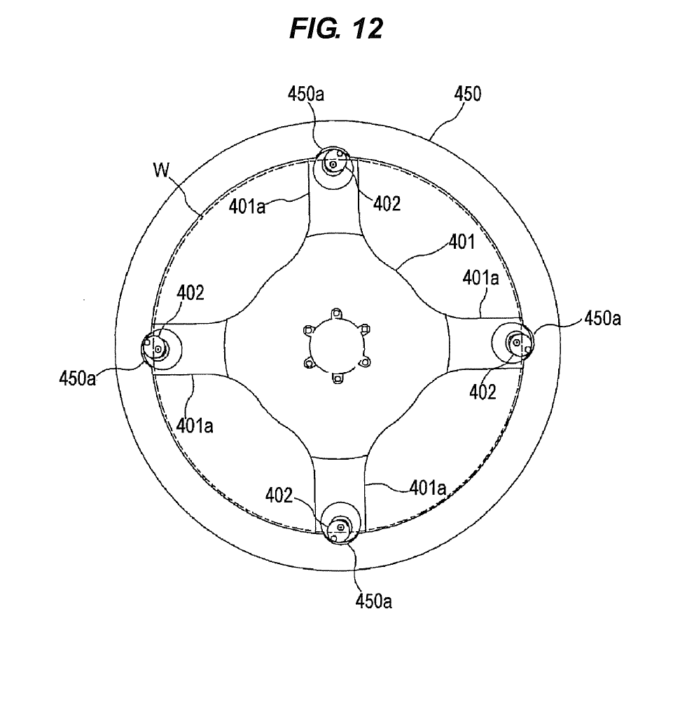

FIG. 11 is a vertical cross-sectional view showing the Rotagoni drier in the drying module 205a, and FIG. 12 is a plan view showing the Rotagoni drier. The drying module 205a is in the form of a box surrounded by outer walls. The outer wall of the drying module 205a has an opening for carrying in and out the substrate W, and a shutter which opens and closes the opening (not shown). As shown in FIGS. 11 and 12, the Rotagoni drier includes a base 401, and four cylindrical substrate-support members 402 supported by the base 401. The base 401 is secured to an upper end of a rotational shaft 405, which is rotatably supported by bearings 406. These bearings 406 are secured to an inner surface of a cylindrical member 407 which extends in parallel with the rotational shaft 405. A lower end of the cylindrical member 407 is mounted on a mount base 409 and is fixed in position. The rotational shaft 405 is coupled to a motor 415 via pulleys 411 and 412 and a belt 414, so that the base 401 is rotated about its own axis by the motor 415.

A spin cover 450 is fixed to the upper surface of the base 401. The spin cover 450 is shown in vertical cross section in FIG. 11. The spin cover 450 is disposed so as to surround the entire circumferential edge of a substrate W. The spin cover 450 has a vertical cross-sectional shape slanted radially inwardly. Further, the vertical cross-section of the spin cover 450 is configured by a smooth curved line. An upper end of the spin cover 450 lies in close proximity to the wafer W, and an inside diameter of the upper end of the spin cover 450 is slightly larger than the diameter of the wafer W. The upper end of the spin cover 450 has notches 450a shaped along the outer circumferential surface of the substrate-support member 402. The notches 450a are located in positions corresponding to the substrate-support members 402. Drain holes 451, which extend obliquely, are formed in a bottom of the spin cover 450.

A front nozzle 454 for supplying pure water as a cleaning liquid onto the surface (front surface) of the substrate W is arranged above the substrate W. The front nozzle 454 is oriented toward the center of the substrate W. The front nozzle 454 is coupled to a non-illustrated pure water supply source (i.e., a cleaning liquid supply source) to supply pure water to the center of the front surface of the substrate W. As a cleaning liquid, other than pure water, a chemical liquid may be used. Two parallel nozzles 460 and 461 for performing Rotagoni drying are disposed above the substrate W. The nozzle 460 is configured to supply an IPA vapor (a mixture of isopropyl alcohol and an N₂ gas) onto the front surface of the substrate W. The nozzle 461 is configured to supply pure water onto the front surface of the substrate W in order to prevent the front surface of the substrate W from being dried. The nozzles 460 and 461 are movable in the radial direction of the substrate W.

The rotational shaft 405 houses therein a back nozzle 463 coupled to a cleaning-liquid supply source 465 and a gas nozzle 464 coupled to a drying-gas supply source 466. The cleaning-liquid supply source 465 stores pure water as a cleaning liquid therein and supplies the pure water through the back nozzle 463 to a rear surface of the substrate W. The drying-gas supply source 466 stores an N₂ gas or dry air as a drying gas therein, and supplies the drying gas through the gas nozzle 464 to the rear surface of the substrate W.

A lifting mechanism 470 for lifting the substrate-support members 402 is disposed around the cylindrical member 407. The lift mechanism 470 is vertically slidable with respect to the cylindrical member 407. The lift mechanism 470 has a plurality of contact plates 470a for contacting the respective lower ends of the substrate-support members 402. A first gas chamber 471 and a second gas chamber 472 are defined between the outer circumferential surface of the cylindrical member 407 and the inner circumferential surface of the lift mechanism 470. The first gas chamber 471 and the second gas chamber 472 are held in fluid communication with a first gas passage 474 and a second gas passage 475, respectively. The first gas passage 474 and the second gas passage 475 have respective ends connected to pressurized gas supply sources (not shown). If the pressure in the first gas chamber 471 is made higher than the pressure in the second gas chamber 472, then the lift mechanism 470 is lifted. If the pressure in the second gas chamber 472 is made higher than the pressure in the first gas chamber 471, then the lift mechanism 470 is lowered. In FIG. 12, the lift mechanism 470 is shown as being in a lowered position.

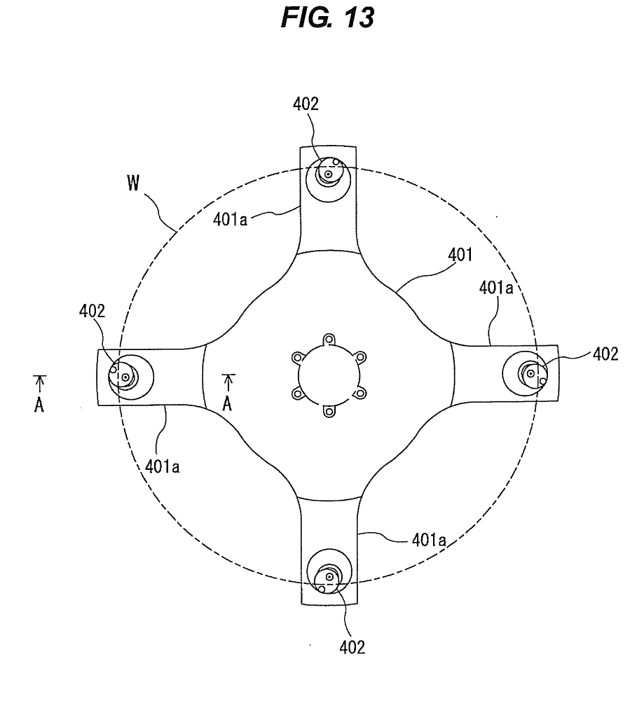

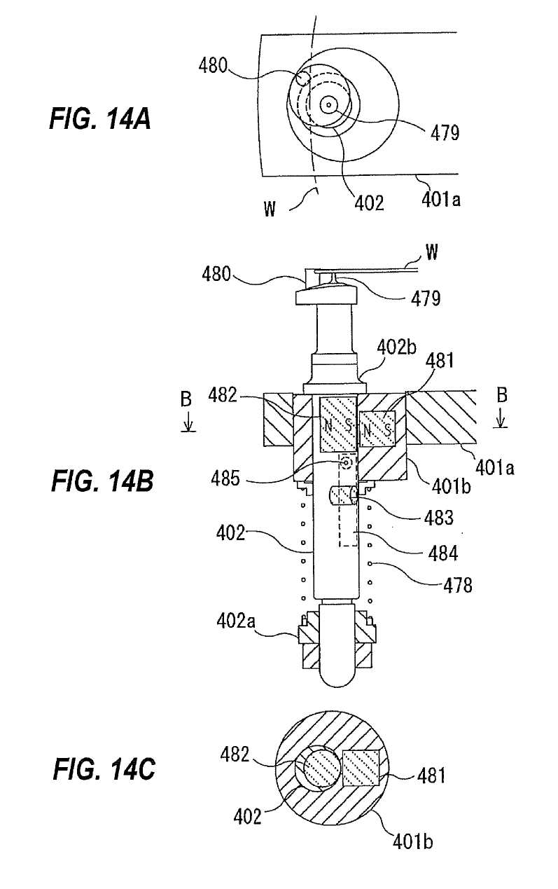

FIG. 13 is a plan view showing the base 401 shown in FIG. 11. As shown in FIG. 13, the base 401 has four arms 401a, and cylindrical substrate-support members 402 are vertically movably supported by tip ends of the respective arms 401a. FIG. 14A is a plan view showing the substrate-support member 402 and part of the base 401 shown in FIG. 13, FIG. 14B is a cross-sectional view taken along line A-A of FIG. 13, and FIG. 14C is a cross-sectional view taken along line B-B of FIG. 14B.

The arm 401a of the base 401 has a holder 401b configured to slidably hold the substrate-support member 402. This holder 401b may be formed integrally with the arm 401a. A vertically-extending through-hole is formed in the holder 401b, and the substrate-support member 402 is inserted in this through-hole. The through-hole has a diameter slightly larger than a diameter of the substrate-support member 402. Therefore, the substrate-support member 402 is movable in the vertical direction relative to the base 401, and the substrate-support member 402 is rotatable about its own axis.

A spring support 402a is attached to a lower portion of the substrate-support member 402. A spring 478 is disposed around the substrate-support member 402, and the spring 478 is supported by the spring support 402a. An upper end of the spring 478 presses the holder 401b (part of the base 401). Therefore, the spring 478 exerts a downward force on the substrate-support member 402. A stopper 402b is formed on an outer circumferential surface of the substrate-support member 402. This stopper 402b has a diameter larger than the diameter of the through-hole. Therefore, a downward movement of the substrate-support member 402 is limited by the stopper 402b, as shown in FIG. 14B.

A support pin 479 on which the substrate W is to be placed and a cylindrical clamp 480 as a substrate holding portion to be brought into contact with the periphery of the substrate W are provided on an upper end of the substrate-support member 402. The support pin 479 is arranged on the axis of the substrate-support member 402. On the other hand, the clamp 480 is arranged away from the axis of the substrate-support member 402. Therefore, as the substrate-support member 402 rotates, the clamp 480 makes revolutions around the axis of the substrate-support member 402. In order to prevent electrostatic charge, portions which are brought into contact with the substrate W are preferably made from a conductive material (preferably iron, aluminum, SUS) or carbon resin (e.g., PEEK or PVC).

A first magnet 481 is attached to the holder 401b of the base 401 so as to face a side surface of the substrate-support member 402. On the other hand, a second magnet 482 and a third magnet 483 are provided in the substrate-support member 402. The second magnet 482 and the third magnet 483 are arranged away from each other in the vertical direction. Neodymium magnet is preferably used as the first, second, and third magnets 481, 482, and 483.

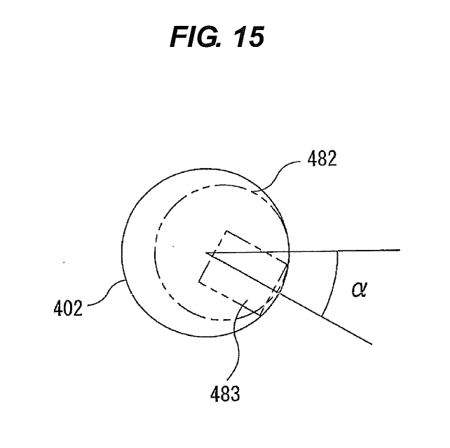

FIG. 15 is a schematic view showing an arrangement of the second magnet 482 and the third magnet 483, as viewed from the axial direction of the substrate-support member 402. As shown in FIG. 15, the second magnet 482 and the third magnet 483 are arranged in different positions with respect to the circumferential direction of the substrate-support member 402. Specifically, a line connecting the second magnet 482 and the center of the substrate-support member 402 and a line connecting the third magnet 483 and the center of the substrate-support member 402 cross at a predetermined angle of α, as viewed from the axial direction of the substrate-support member 402.

When the substrate-support member 402 is in the lowered position as shown in FIG. 14B, the first magnet 481 and the second magnet 482 face each other. At this time, an attractive force acts between the first magnet 481 and the second magnet 482. This attractive force generates a force of rotating the substrate-support member 402 about its own axis in a direction such that the clamp 480 presses the periphery of the substrate W. Accordingly, the lowered position shown in FIG. 14B is a clamp position in which the substrate W is held (clamped).

The first magnet 481 and the second magnet 482 are not necessarily required to face each other when holding the substrate W, as long as they are close enough to produce a sufficient holding force. For example, even when the first magnet 481 and the second magnet 482 tilt with respect to each other, the magnet force is produced between these magnets, as long as they are close to each other. Therefore, it is not necessary that the first magnet 481 and the second magnet 482 always face each other when holding the substrate W, as long as the magnet force is large enough to rotate the substrate-support member 402 to hold the substrate W.

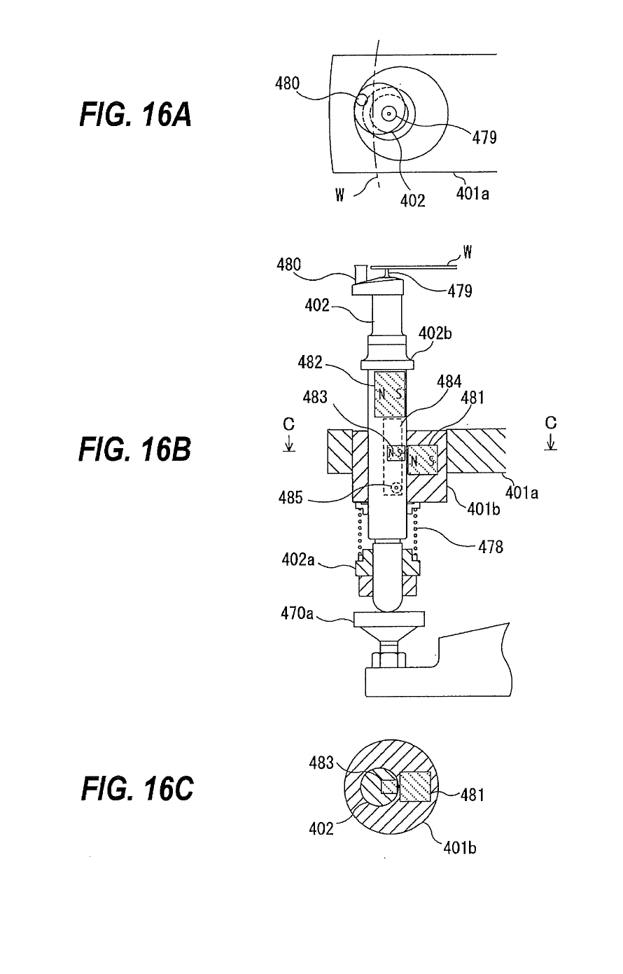

FIG. 16A is a plan view showing the substrate-support member 402 and part of the arm 401a when the substrate-support member 402 is elevated by the lifting mechanism 470, and FIG. 16B is a cross-sectional view taken along line A-A of FIG. 13 when the substrate-support member 402 is elevated by the lifting mechanism 470, and FIG. 16C is a cross-sectional view taken along line C-C of FIG. 16B.

When the substrate-support member 402 is elevated by the lifting mechanism 470 to the elevated position as shown in FIG. 16B, the first magnet 481 and the third magnet 483 face each other, and the second magnet 482 is away from the first magnet 481. At this time, an attractive force acts between the first magnet 481 and the third magnet 483. This attractive force generates a force of rotating the substrate-support member 402 about its own axis in a direction such that the clamp 480 moves away from the substrate W. Accordingly, the elevated position shown in FIG. 16B is an unclamp position in which the substrate W is released (unclamped). In this case also, the first magnet 481 and the third magnet 483 are not necessarily required to face each other when releasing the substrate W, as long as they are close enough to produce a sufficient force (magnet force) of rotating the substrate-support member 402 in a direction such that the clamp 480 is moved away from the substrate W.

Because the second magnet 482 and the third magnet 483 are arranged in different positions with respect to the circumferential direction of the substrate-support member 402, the rotating force acts on the substrate-support member 402 as the substrate-support member 402 moves up and down. This rotating force provides the clamp 480 with a force of holding the substrate W and a force of releasing the substrate W. Therefore, only by moving the substrate-support member 402 vertically, the clamp 480 can hold the substrate W and release the substrate W. In this manner, the first magnet 481, the second magnet 482, and the third magnet 483 functions as a holding mechanism (rotating mechanism) for rotating the substrate-support member 402 about its own axis to cause the clamp 480 to hold the substrate W. This holding mechanism (rotating mechanism) is operated by the vertical movements of the substrate-support member 402.

The contact plates 470a of the lifting mechanism 470 are located below the substrate-support members 402. When the contact plates 470a move upward, the upper surfaces of the contact plates 470a are brought into contact with the lower ends of the substrate-support members 402, and the substrate-support members 402 are elevated by the contact plates 470a against the pressing forces of the springs 478. The upper surface of each contact plate 470a is a flat surface, and on the other hand, the lower end of each substrate-support member 402 is in the shape of hemisphere. In this embodiment, the lifting mechanism 470 and the springs 478 constitute a drive mechanism for moving the substrate-support members 402 in the vertical direction. It is to be noted that the drive mechanism is not limited to this embodiment. For example, a servomotor may be used as the drive mechanism.

A groove 484 is formed on the side surface of each substrate-support member 402. This groove 484 extends along the axis of the substrate-support member 402, and has an arc-shaped horizontal cross section. A protrusion 485 projecting toward the groove 484 is fanned on the arm 401a (the holder 401b in this embodiment) of the base 401. A tip end of this protrusion 485 lies in the groove 484, and the protrusion 485 roughly engages with the groove 484. The groove 484 and the protrusion 485 are provided for limiting a rotation angle of the substrate-support member 402.

Next, operations of the drying module 205a with the above-described structures will be described.

First, the substrate W and the spin cover 450 are rotated in unison by the motor 415. In this state, the front nozzle 454 and the back nozzle 463 supply the pure water onto the front surface (upper surface) and the rear surface (lower surface) of the substrate W to rinse the substrate W in its entirety with the pure water. The pure water, supplied to the substrate W, spreads over the front surface and the rear surface via the centrifugal force, thereby rinsing all the surfaces of the substrate W. The pure water, that is spun off from the rotating substrate W, is captured by the spin cover 450 and flows into the drain holes 451. During the rising process of the substrate W, the two nozzles 460 and 461 are in their given idle positions away from the substrate W.

Then, supply of the pure water from the front nozzle 454 is stopped, and the front nozzle 454 is moved to its given idle position away from the substrate W. The two nozzles 460 and 461 are moved to their operating positions above the substrate W. While the substrate W is being rotated at a low speed ranging from 30 to 150 min⁻¹, the nozzle 460 supplies the IPA vapor and the nozzle 461 supplies the pure water onto the front surface of the substrate W. During this operation, the back nozzle 463 supplies the pure water to the rear surface of the substrate W. The two nozzles 460 and 461 are simultaneously moved in the radial direction of the substrate W, whereby the front surface (upper surface) of the substrate W is dried.

Thereafter, the two nozzles 460 and 461 are moved to their idle positions, and supply of the pure water from the back nozzle 463 is stopped. Then, the substrate W is rotated at a high speed ranging from 1000 to 1500 min⁻¹, thereby removing the pure water from the rear surface of the substrate W. During this operation, the gas nozzle 464 supplies the drying gas to the rear surface of the substrate W. Thus, the rear surface of the substrate W is dried. The dried substrate W is removed from the drying module 205a by the transport robot 22 shown in FIG. 1, and is returned to the substrate cassette. In this manner, a series of processes including polishing, cleaning, and drying of the substrate is performed.

The drying module 205a according to the above-described structures can dry both upper and lower surfaces of the substrate W promptly and effectively, and can accurately control an endpoint of the drying operation. Therefore, the drying process does not become a rate-limiting step in the overall cleaning process. Moreover, because the processing times in the multiple cleaning lines formed in the cleaning section 4 can be equalized, the throughput of the processes in their entirety can be improved.

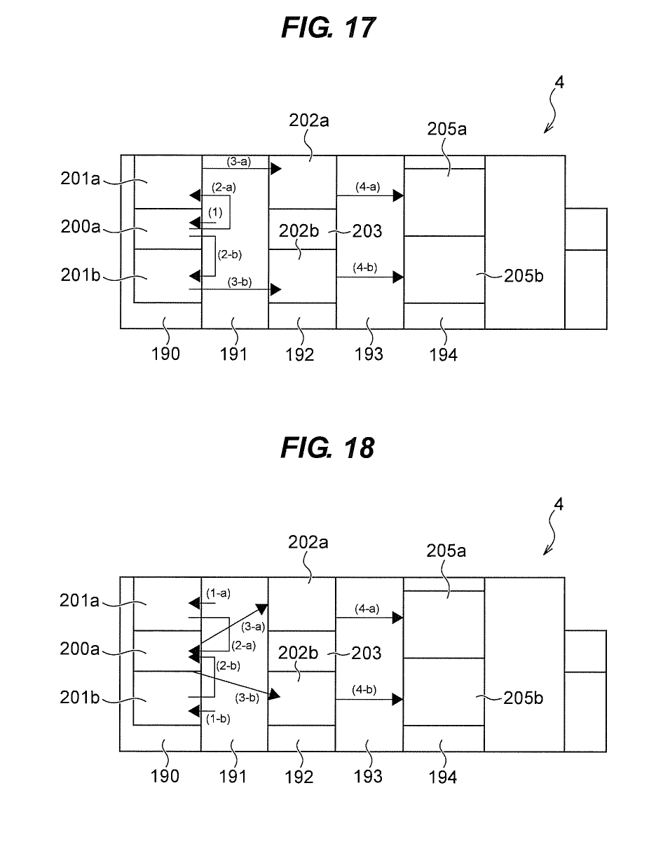

According to a processing sequence, a substrate that is transported to the substrate station 203 of the cleaning section 4 is cleaned while it is being transported through the first cleaning module 200a, one of the second cleaning modules 201a, 201b, and one of the third cleaning modules 202a, 202b, and the cleaned substrate is then transported to one of the drying modules 205a, 205b. Such a processing sequence will be described below with reference to FIG. 17. In this processing sequence, the substrate may not be transported to the substrate station 203, but may be directly transported from the temporary placement table 180 to the first cleaning module 200a by the first transport robot 240. The processing sequence is suitable for cleaning a substrate deposited with a large amount of slurry and polishing debris after it has been polished. According to the processing sequence, the slurry and the polishing debris are initially removed from the substrate by a rinsing cleaning process, and thereafter the substrate is subjected to roll scrub cleaning. Therefore, the substrate is prevented from being damaged and from being redeposited with particles.

First, a substrate that is removed from the substrate station 203 is transported to the first cleaning module 200a along a route (1), and rinsed by the first cleaning module (rinsing cleaning module) 200a. The rinsed substrate is transported alternatively along two cleaning lines, i.e., a first cleaning line and a second cleaning line.

On the first cleaning line, the substrate is initially transported from the first cleaning module 200a to the second cleaning module 201a located at the upper part of the first cleaning chamber 190 along a route (2-a). After the substrate is subjected to the roll scrub cleaning by the second cleaning module (roll scrub cleaning module) 201a, the substrate is transported to the third cleaning module 202a located at the upper part of the second cleaning chamber 192 along a route (3-a). The substrate is subjected to the roll scrub cleaning again by the third cleaning module (roll scrub cleaning module) 202a. Thereafter, the substrate is transported to the drying module 205a located at the upper part of the drying chamber 194 along a route (4-a).

On the second cleaning line, the substrate is initially transported from the first cleaning module 200a to the second cleaning module 201b located at the lower part of the first cleaning chamber 190 along a route (2-b). After the substrate is subjected to the roll scrub cleaning by the second cleaning module (roll scrub cleaning module) 201b, the substrate is transported to the third cleaning module 202b located at the lower part of the second cleaning chamber 192 along a route (3-b). The substrate is subjected to the roll scrub cleaning again by the third cleaning module (roll scrub cleaning module) 202b. Thereafter, the substrate is transported to the drying module 205b located at the lower part of the drying chamber 194 along a route (4-b). Consequently, a plurality of (typically two) substrates can essentially simultaneously be cleaned and dried on the two parallel cleaning lines.

According to another processing sequence, a substrate that is transported to the substrate station 203 of the cleaning section 4 is cleaned while it is being transported through one of the second cleaning modules 201a, 201b, the first cleaning module 200a, and one of the third cleaning modules 202a, 202b, and the cleaned substrate is then transported to one of the drying modules 205a, 205b. Such a processing sequence will be described below with reference to FIG. 18. In this processing sequence, the substrate may not be transported to the substrate station 203, but may be directly transported from the temporary placement table 180 to the one of the second cleaning modules 201a, 201b by the first transport robot 240. The processing sequence can meet demands to perform roll scrub cleaning of an oxide film or the like on a surface of a substrate using an acid chemical solution and then to perform rinsing cleaning of the substrate with pure water or the like. The substrate is transported alternatively along two cleaning lines, i.e., a first cleaning line and a second cleaning line.

On the first cleaning line, the substrate that is removed from the substrate station 203 is initially transported to the second cleaning module 201a located at the upper part of the first cleaning chamber 190 along a route (1-a). After the substrate is subjected to the roll scrub cleaning by the second cleaning module (roll scrub cleaning module) 201a, the substrate is transported to the first cleaning module 200a along a route (2-a) and rinsed by the first cleaning module (rinsing cleaning module) 200a. Then, the substrate is transported to the third cleaning module 202a located at the upper part of the second cleaning chamber 192 along a route (3-a). The substrate is subjected to the roll scrub cleaning again by the third cleaning module (roll scrub cleaning module) 202a. Thereafter, the substrate is transported to the drying module 205a located at the upper part of the drying chamber 194 along a route (4-a).

On the second cleaning line, the substrate that is removed from the substrate station 203 is initially transported to the second cleaning module 201b located at the lower part of the first cleaning chamber 190 along a route (1-b). After the substrate is subjected to the roll scrub cleaning by the second cleaning module (roll scrub cleaning module) 201b, the substrate is transported to the first cleaning module 200a along a route (2-b) and rinsed by the first cleaning module (rinsing cleaning module) 200a. Then, the substrate is transported to the third cleaning module 202b located at the lower part of the second cleaning chamber 192 along a route (3-b). The substrate is subjected to the roll scrub cleaning again by the third cleaning module (roll scrub cleaning module) 202b. Thereafter, the substrate is transported to the drying module 205b located at the lower part of the drying chamber 194 along a route (4-b).

Since the cleaning section 4 has the two second cleaning modules 201a, 201b, even if a preceding substrate is being cleaned by one of the second cleaning modules 201a, 201b, the substrate to be cleaned may be introduced into and cleaned by the other one of the second cleaning modules 201a, 201b. Therefore, the cleaning section 4 is capable of not only achieving a high throughput, but also cleaning the substrate immediately after it is polished.

The concentration of the cleaning liquid used in the second cleaning modules 201a, 201b may be different from the concentration of the cleaning liquid used in the third cleaning modules 202a, 202b. For example, the concentration of the cleaning liquid used in the second cleaning modules 201a, 201b may be higher than the concentration of the cleaning liquid used in the third cleaning modules 202a, 202b. Usually, the cleaning capability of the cleaning liquid is considered to be substantially proportional to the concentration of the cleaning liquid and the cleaning time. Therefore, in the case where the concentration of the cleaning liquid used in the second cleaning modules 201a, 201b is high, even when the substrate to be cleaned is badly contaminated, the cleaning time consumed in the second cleaning modules 201a, 201b may be substantially equal to the cleaning time consumed in the third cleaning modules 202a, 202b.

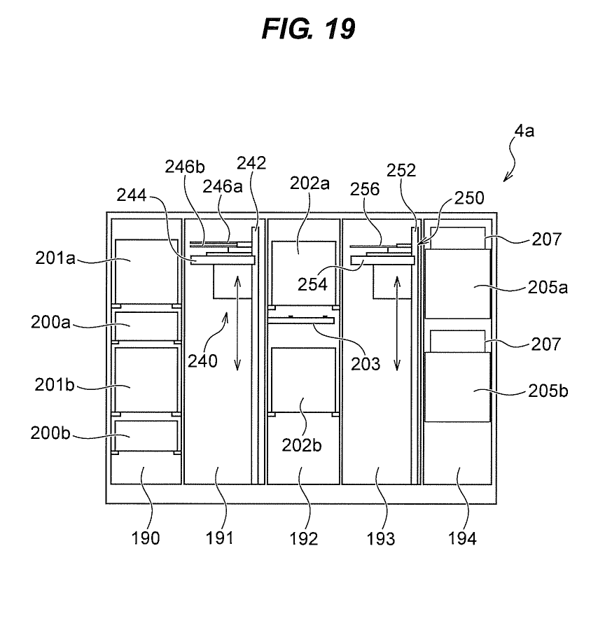

FIG. 19 is a front view showing another cleaning section 4a. The cleaning section 4a is different from the above cleaning section 4 in that the cleaning section 4a additionally includes another first cleaning module 200b which is structurally identical to the existing first cleaning module 200a and the first cleaning module 200b is disposed vertically below the second cleaning module 201b located at the lower part of the first cleaning chamber 190.

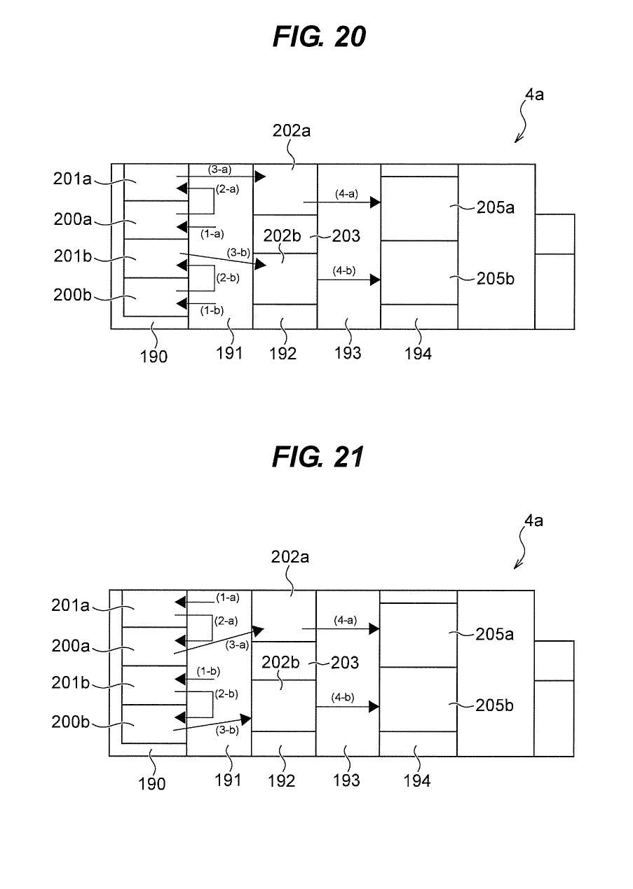

According to a cleaning sequence, a substrate that is transported to the substrate station 203 of the cleaning section 4a is cleaned while it is being transported through one of the first cleaning modules 200a, 200b, one of the second cleaning modules 201a, 201b, and one of the third cleaning modules 202a, 202b, and then the cleaned substrate is transported to one of the drying modules 205a, 205b. Such a processing sequence will be described below with reference to FIG. 20. In this processing sequence, the substrate is transported alternatively along two cleaning lines, i.e., a first cleaning line and a second cleaning line.

On the first cleaning line, the substrate that is removed from the substrate station 203 is initially transported to the first cleaning module 200a located at the upper part of the first cleaning chamber 190 along a route (1-a). After the substrate is subjected to the rinsing cleaning by the first cleaning module (rinsing cleaning module) 200a, the substrate is transported to the second cleaning module 201a located at the upper part of the first cleaning chamber 190 along a route (2-a), and the substrate is subjected to the roll scrub cleaning by the second cleaning module (roll scrub cleaning module) 201a. Then, the substrate is transported to the third cleaning module 202a located at the upper part of the second cleaning chamber 192 along a route (3-a), and the substrate is subjected to the roll scrub cleaning again by the third cleaning module (roll scrub cleaning module) 202a. Thereafter, the substrate is transported to the drying module 205a located at the upper part of the drying chamber 194 along a route (4-a).

On the second cleaning line, the substrate that is removed from the substrate station 203 is initially transported to the first cleaning module 200b located at the lower part of the first cleaning chamber 190 along a route (1-b). After the substrate is subjected to the rinsing cleaning by the first cleaning module (rinsing cleaning module) 200b, the substrate is transported to the second cleaning module 201b located at the lower part of the first cleaning chamber 190 along a route (2-b), and the substrate is subjected to the roll scrub cleaning by the second cleaning module (roll scrub cleaning module) 201b. Then, the substrate is transported to the third cleaning module 202b located at the lower part of the second cleaning chamber 192 along a route (3-b), and the substrate is subjected to the roll scrub cleaning again by the third cleaning module (roll scrub cleaning module) 202b. Thereafter, the substrate is transported to the drying module 205b located at the lower part of the drying chamber 194 along a route (4-b).

According to another processing sequence, a substrate that is transported to the substrate station 203 of the cleaning section 4a is cleaned while it is being transported through one of the second cleaning modules 201a, 201b, one of the first cleaning modules 200a, 200b, and one of the third cleaning modules 202a, 202b, and then the cleaned substrate is transported to one of the drying modules 205a, 205b. Such a processing sequence will be described below with reference to FIG. 21. In this processing sequence, the substrate is transported alternatively along two cleaning lines, i.e., a first cleaning line and a second cleaning line.

On the first cleaning line, the substrate that is removed from the substrate station 203 is initially transported to the second cleaning module 201a located at the upper part of the first cleaning chamber 190 along a route (1-a). After the substrate is subjected to the roll scrub cleaning by the second cleaning module (roll scrub cleaning module) 201a, the substrate is transported to the first cleaning module 200a located at the upper part of the first cleaning chamber 190 along a route (2-a) and rinsed by the first cleaning module (rinsing cleaning module) 200a. Then, the substrate is transported to the third cleaning module 202a located at the upper part of the second cleaning chamber 192 along a route (3-a), and the substrate is subjected to the roll scrub cleaning again by the third cleaning module (roll scrub cleaning module) 202a. Thereafter, the substrate is transported to the drying module 205a located at the upper part of the drying chamber 194 along a route (4-a).

On the second cleaning line, the substrate that is removed from the substrate station 203 is initially transported to the second cleaning module 201b located at the lower part of the first cleaning chamber 190 along a route (1-b). After the substrate is subjected to the roll scrub cleaning by the second cleaning module (roll scrub cleaning module) 201b, the substrate is transported to the first cleaning module 200b located at the lower part of the first cleaning chamber 190 along a route (2-b) and rinsed by the first cleaning module (rinsing cleaning module) 200b. Then, the substrate is transported to the third cleaning module 202b located at the lower part of the second cleaning chamber 192 along a route (3-b), and the substrate is subjected to the roll scrub cleaning again by the third cleaning module (roll scrub cleaning module) 202b. Thereafter, the substrate is transported to the drying module 205b located at the lower part of the drying chamber 194 along a route (4-b).

As described above, the cleaning section 4a has the two first cleaning modules 200a, 200b, so that the first through third cleaning modules are provided in a one-on-one correspondence for achieving an increased throughput.

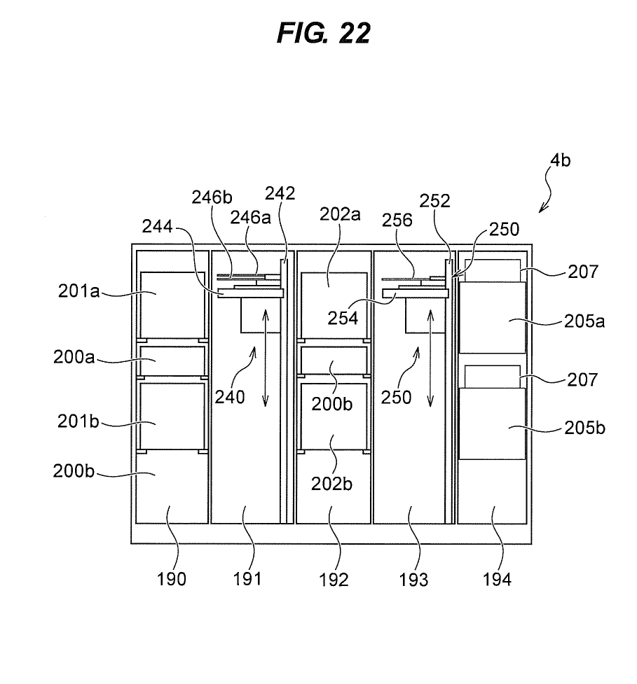

FIG. 22 is a front view showing still another cleaning section 4b. The cleaning section 4b is different from the above cleaning section 4 in that the cleaning section 4b additionally includes another first cleaning module 200b which is structurally identical to the existing first cleaning module 200a without having the substrate station and the first cleaning module 200b is disposed vertically between the third cleaning modules 202a, 202b.

In this embodiment, the first transport robot 240 disposed in the first transport chamber 191 operates to transfer the substrate to one of the first cleaning module 200a in the first cleaning chamber 190 and the first cleaning module 200b in the second cleaning chamber 192, to transfer the substrate to one of the second cleaning modules 201a, 201b in the first cleaning chamber 190, and to transfer the substrate between the first cleaning module 200b and one of the third cleaning modules 202a, 202b in the second cleaning chamber 192.

In this embodiment, the cleaning section 4b is free of a substrate station, and thus a substrate that is temporarily placed on the temporary placement table 180 is introduced into the cleaning section 4b.

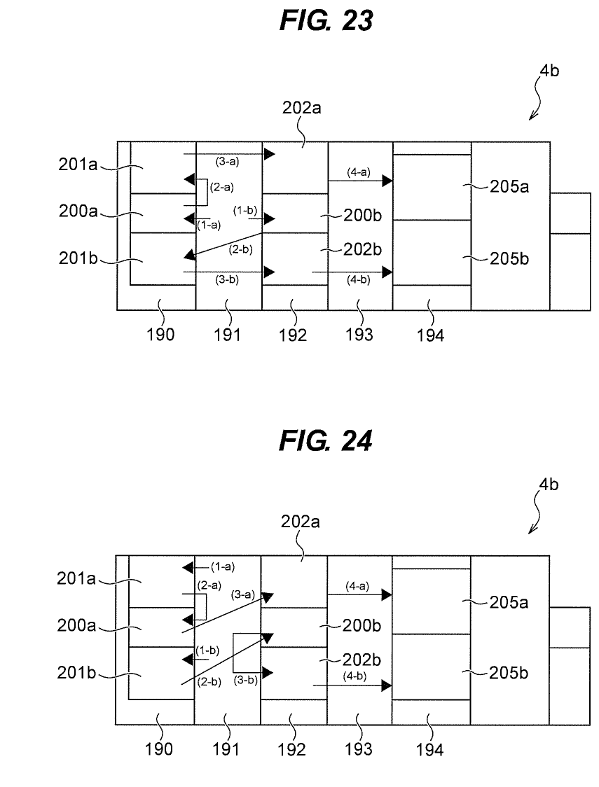

According to a cleaning sequence in the cleaning section 4b, a substrate that is temporarily placed on the temporary placement table 180 is cleaned while it is being transported through one of the first cleaning modules 200a, 200b, one of the second cleaning modules 201a, 201b, and one of the third cleaning modules 202a, 202b, and then the cleaned substrate is transported to one of the drying modules 205a, 205b. Such a processing sequence will be described below with reference to FIG. 23. In this processing sequence, the substrate is transported alternatively along two cleaning lines, i.e., a first cleaning line and a second cleaning line.

On the first cleaning line, the substrate that is temporarily placed on the temporary placement table 180 is initially transported to the first cleaning module 200a in the first cleaning chamber 190 along a route (1-a). After the substrate is subjected to the rinsing cleaning by the first cleaning module (rinsing cleaning module) 200a, the substrate is transported to the second cleaning module 201a located at the upper part of the first cleaning chamber 190 along a route (2-a), and the substrate is subjected to the roll scrub cleaning by the second cleaning module (roll scrub cleaning module) 201a. Then, the substrate is transported to the third cleaning module 202a located at the upper part of the second cleaning chamber 192 along a route (3-a), and the substrate is subjected to the roll scrub cleaning again by the third cleaning module (roll scrub cleaning module) 202a. Thereafter, the substrate is transported to the drying module 205a located at the upper part of the drying chamber 194 along a route (4-a).

On the second cleaning line, the substrate that is temporarily placed on the temporary placement table 180 is initially transported to the first cleaning module 200b in the second cleaning chamber 192 along a route (1-b). After the substrate is subjected to the rinsing cleaning by the first cleaning module (rinsing cleaning module) 200b, the substrate is transported to the second cleaning module 201b located at the lower part of the first cleaning chamber 190 along a route (2-b). The substrate is subjected to the roll scrub cleaning by the second cleaning module (roll scrub cleaning module) 201b. Thereafter, the substrate is transported to the third cleaning module 202b located at the lower part of the second cleaning chamber 192 along a route (3-b), and the substrate is subjected to the roll scrub cleaning again by the third cleaning module (roll scrub cleaning module) 202b. Thereafter, the substrate is transported to the drying module 205b located at the lower part of the drying chamber 194 along a route (4-b).

According to another cleaning sequence, a substrate that is temporarily placed on the temporary placement table 180 is cleaned while it is being transported through one of the second cleaning modules 201a, 201b, one of the first cleaning modules 200a, 200b, and one of the third cleaning modules 202a, 202b, and then the cleaned substrate is transported to one of the drying modules 205a, 205b. Such a processing sequence will be described below with reference to FIG. 24. In this processing sequence, the substrate is transported alternatively along two cleaning lines, i.e., a first cleaning line and a second cleaning line.

On the first cleaning line, the substrate that is temporarily placed on the temporary placement table 180 is initially transported to the second cleaning module 201a located at the upper part of the first cleaning chamber 190 along a route (1-a). After the substrate is subjected to the roll scrub cleaning by the second cleaning module (roll scrub cleaning module) 201a, the substrate is transported to the first cleaning module 200a in the first cleaning chamber 190 along a route (2-a), and the substrate is subjected to the rinsing cleaning by the first cleaning module (rinsing cleaning module) 200a. Then, the substrate is transported to the third cleaning module 202a located at the upper part of the second cleaning chamber 192 along a route (3-a), and the substrate is subjected to the roll scrub cleaning again by the third cleaning module (roll scrub cleaning module) 202a. Thereafter, the substrate is transported to the drying module 205a located at the upper part of the drying chamber 194 along a route (4-a).

On the second cleaning line, the substrate that is temporarily placed on the temporary placement table 180 is initially transported to the second cleaning module 201b located at the lower part of the first cleaning chamber 190 along a route (1-b). After the substrate is subjected to the roll scrub cleaning by the second cleaning module (roll scrub cleaning module) 201b, the substrate is transported to the first cleaning module 200b in the second cleaning chamber 192 along a route (2-b), and the substrate is subjected to the rinsing cleaning by the first cleaning module (rinsing cleaning module) 200b. Then, the substrate is transported to the third cleaning module 202b located at the lower part of the second cleaning chamber 192 along a route (3-b), and the substrate is subjected to the roll scrub cleaning again by the third cleaning module (roll scrub cleaning module) 202b. Thereafter, the substrate is transported to the drying module 205b located at the lower part of the drying chamber 194 along a route (4-b).

As described above, according to the substrate processing apparatus of the present invention, while achieving an increased throughput and promoting space saving, the substrate can be cleaned by the first cleaning module 200a and then cleaned by either one of the two second cleaning modules 201a, 201b in the first cleaning chamber 190, and thereafter the substrate can be further cleaned by one of the third cleaning modules 202a, 202b in the second cleaning chamber 192; or the substrate can be cleaned by either one of the two second cleaning modules 201a, 201b in the first cleaning chamber 190 and then cleaned by the first cleaning module 200a in the first cleaning chamber 190, and thereafter the substrate can be further cleaned by one of the third cleaning modules 202a, 202b in the second cleaning chamber 192. Specifically, the initial cleaning is performed using the first cleaning module 200a or performed using either one of the two second cleaning modules 201a, 201b. Thus, the substrate processing apparatus is capable of flexibly dealing with a change of cleaning patterns so as to respond to different film properties of an oxide film or the like on the substrate, for example.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims and equivalents.

What is claimed is:

1. A substrate processing apparatus comprising:
a first cleaning chamber which houses at least one first cleaning module and two second cleaning modules, said first cleaning module and said two second cleaning modules being arranged in a vertical array;
a second cleaning chamber which houses two third cleaning modules arranged in a vertical array; and
a first transport robot housed in a first transport chamber disposed between said first cleaning chamber and said second cleaning chamber, said first transport robot being configured to transfer substrates between said first cleaning module, said second cleaning modules, and said third cleaning modules.

2. The substrate processing apparatus according to claim 1, wherein said first transport robot includes a lifting and lowering table which is vertically movable, and two hands mounted on said lifting and lowering table and configured to operate independently of each other for holding the substrates.

3. The substrate processing apparatus according to claim 1, wherein said first cleaning module comprises a rinsing cleaning module and each of said second cleaning modules comprises a roll scrub cleaning module.

4. The substrate processing apparatus according to claim 1, wherein said first cleaning chamber houses said one first cleaning module; and
said second cleaning chamber houses another first cleaning module, said another first cleaning module and said third cleaning modules being arranged in a vertical array in said second cleaning chamber.

5. The substrate processing apparatus according to claim 1, further comprising:
a drying chamber which houses two drying modules arranged in a vertical array;
a second transport robot housed in a second transport chamber disposed between said drying chamber and said second cleaning chamber, said second transport robot being configured to transfer substrates between said third cleaning modules in said second cleaning chamber and said drying modules in said drying chamber.

6. A substrate processing apparatus comprising:
a cleaning chamber which houses a plurality of cleaning modules arranged in a vertical array;
a pair of rails disposed in said cleaning chamber and configured to support one of said cleaning modules; and
at least three sets of rollers provided on a lower surface of said cleaning module and configured to move on said rails;
wherein said pair of rails have recesses defined in upper surfaces thereof at positions aligned with the respective rollers when said cleaning module is located at a predetermined position in said cleaning chamber; and
said pair of rails and said at least three sets of roller are configured such that only one set of rollers is located at position aligned with ones of said recesses of said pair of rails and at least the other two sets of rollers are held in contact with said pair of rails when said cleaning module is not located at said predetermined position in said cleaning chamber.
